(19) United States
(12) Patent Application Publication
(10) Pub. No.: US 2016/0131178 A1
(43) Pub. Date: May 12, 2016

(54) FASTENING STRUCTURE OF CONTROL BOARD TO METALLIC CASE

(71) Applicant: TOYOTA JIDOSHA KABUSHIKI KAISHA, Toyota-shi, Aichi-ken (JP)

(72) Inventor: Kenjiro SHIBA, Takahama-shi, Aichi-ken (JP)

(73) Assignee: TOYOTA JIDOSHA KABUSHIKI KAISHA, Toyota-shi, Aichi-ken (JP)

(21) Appl. No.: 14/897,435

(22) PCT Filed: May 30, 2014
(86) PCT No.: PCT/IB2014/000897

§ 371 Date: Dec. 10, 2015

(30) Foreign Application Priority Data
Jun. 11, 2013 (JP) 2013-122613

(51) Int. Cl. F16B 43/00; F16B 41/00; H05K 5/02

(52) U.S. Cl. CPC F16B 43/00; H05K 5/0204; F16B 41/002

(57) ABSTRACT

A PCU is placed directly on an on-vehicle transaxle (100). A fastening structure for fastening a control board (34) to a PCU case (12) includes a nut (18) that is disposed on an inner surface of the PCU case (12) and in which a female screw (20) is provided; a bolt (22) that is disposed in a fixing hole (40) provided in the control board (34) and is screwed with the nut (18); and a washer (30) that is made of a viscoelastic material, intervenes between a head (25) of the bolt (22) and the control board (34), wherein the bolt (22) includes a male screw section (28) screwed to the female screw (20), an intermediate section (26), and a head (25).

### BACKGROUND OF THE INVENTION

1. Field of the Invention

The present invention relates to a fastening structure for fastening a control board to a metallic case of a power control unit (hereinafter, referred to as “PCU”) that is mounted directly on an on-vehicle transaxle.

2. Description of Related Art

Electric vehicles such as a hybrid automobile and an electric automobile are widely in use. On such an electric vehicle, a PCU that incorporates an inverter and a step up/down converter for controlling electric power supplied to a motor or generated by a generator is mounted. In a PCU case, usually, electronic components that provide the inverter and the step up/down converter, for example, a reactor, a capacitor, a switching element, and a control board that controls a drive of the switching element are accommodated.

Recently, someone proposes to directly fixes the PCU to an upper section or a side surface section of a case of a transaxle (Japanese Patent Application Publication No. 2013-51848 (JP 2013-51848 A), for example). The transaxle is obtained by housing and unitizing a motor generator and a group of transmission gears in a transaxle case.

Since the transaxle vibrates accompanying a drive of the motor generator and the like, when the PCU is directly placed on the case of the transaxle, both of a level of vibration and a frequency added to the PCU becomes larger. Therefore, in the case where the PCU is directly placed on the transaxle case, as an anti-vibration measure, the stiffness of a bracket that fixes the control board in the PCU case had to be improved. However, since a conventional board-fixing bracket is made of a resin in many cases, in order to improve the stiffness, a thickness of the bracket has to be increased, or a rib has to be added, therefore, there occurred another problem of an increase in a size of the PCU. Further, since the resin is nonconductive and low in the thermal conductivity, for grounding and heat release of the control board, components such as a bus bar or a Sarcon sheet are separately necessary, and problems of cost or further increase in size are generated.

In place of the board fixing bracket, it is considered to directly fix to a PCU case that has conductivity and is made of metal having high stiffness and thermal conductivity. By fixing directly to the PCU case, the resinous bracket becomes unnecessary, and without increasing a size of the PCU case, the stiffness of a board fixing section can be improved. Further, when the control board is directly fastened to an inner surface of the metallic case at multipoint, the stiffness of the control board itself can be improved, and when a fastening seat face is used to ground and to release heat, the components such as the bus bar and Sarcon sheet can be omitted, that is, an increase in cost and size can be prevented.

However, in the case when the control board is fastened directly to the metallic PCU case at multipoint, there was fear that accompanying a temperature change, stress may be generated in the control board. That is, it is usual that the control board is provided by soldering a circuit element on a printed-wiring board, which is provided by forming a circuit pattern with a copper foil on a glass fiber reinforced epoxy resin plate. Linear expansion coefficients are different between the printed-wiring board and a metal that provides the PCU case. Therefore, the printed-wiring board cannot follow expansion and contraction of the metallic case, which are generated accompanying the temperature change, and stress in a surface direction is applied on the printed-wiring board. There was fear that due to the stress action, the printed-wiring board and the circuit pattern are fatigued and broken, and cracks may be generated in a soldered section of a circuit element mounted on the printed-wiring board.

Japanese Patent Application Publication No. 2001-332878 (JP 2001-332878 A) discloses a screw fastening structure of an electronic device in which a member (board and the like) to be fastened, on which an electronic component is mounted is screwed and fastened to a female screw provided in a chassis (case) with a screw. In JP 2001-332878 A, a screw is a stepped screw that has a head, an unthreaded section having a diameter smaller than that of the head and a male screw, and an O-ring is disposed between the head of the screw and the chassis. However, since JP 2001-332878 A does not relates to a technique for fastening a control board to a PCU case directly placed on a transaxle, a measure against vibration generated in the transaxle is not fully studied.

### SUMMARY OF THE INVENTION

In view of the problems described above, the present invention provides a fastening structure for fastening a control board to a metallic case of a PCU that is disposed directly on a transaxle, in which, while reducing an influence of a vibration from the transaxle, the control board can be fastened with a fastening force capable of absorbing a thermal expansion difference between the case and the board.

According to one viewpoint of the present invention, a fastening structure for fastening a control board to a metallic case of a power control unit that is placed directly on an on-vehicle transaxle is provided. The fastening structure includes a nut section, a bolt and a washer made of a viscoelastic material. The nut section is disposed on an inner surface of the metallic case and has a female screw. The bolt is disposed in a fixing hole provided in the control board and the bolt is screwed with the nut section. The washer made of a viscoelastic material is provided between a head of the bolt and the control board, and the washer comes into surface contact with a bottom surface of the head of the bolt and a top surface of the control board. The bolt includes a male screw section, an intermediate section and a head. The male screw section is screwed with the female screw. The intermediate section has a diameter larger than that of the male screw section and smaller than that of the fixing hole. In the intermediate section, a stepped surface with the male screw section contacts with a seat face that is an end surface of the nut section. The head that has a diameter larger than that of the intermediate section. A bottom surface of the head contacts with a top surface of the washer made of the viscoelastic material.

Further, in the fastening structure, a protrusion section may be provided on an inner peripheral surface of the washer made of the viscoelastic material. The protrusion section protrudes inwardly and contacts with an outer peripheral surface of the intermediate section of the bolt. Still further, a metallic washer may be provided between the washer made of the viscoelastic material and the head of the bolt.

Further, in the fastening structure, a friction-reducing coating may be applied on at least one of the top surface of the washer made of the viscoelastic material and the bottom surface of the head of the bolt. Further, in the fastening structure, a recess section may be provided on a part of a surface where the nut section comes into surface contact with the control board.

Still further, in the fastening structure, the fastening structure may have a structure where the control board is fastened to the metallic case at a plurality of positions, only one of the plurality of the fastening positions is rigid-fixed with a washer not made of the viscoelastic material, and the remaining positions are fastened with the washers made of the viscoelastic material.

According to the fastening structure of the present invention as described above, since the washer made of the viscoelastic material can absorb difference of linear expansion coefficients between the metallic case and the control board and vibration, while reducing an influence of the vibration, the control board can be suitably fastened.

### BRIEF DESCRIPTION OF THE DRAWINGS

Features, advantages, and technical and industrial significance of exemplary embodiments of the invention will be described below with reference to the accompanying drawings, in which like numerals denote like elements, and wherein:

FIG. 1 is a diagram that shows a PCU placed directly on a transaxle;

FIG. 2A is a diagram that shows a fastening structure according to a present embodiment in which a washer that has a protrusion section and is made of a viscoelastic material is used;

FIG. 2B is a diagram that shows a fastening structure according to the present embodiment in which a washer that does not have a protrusion section and is made of the viscoelastic material is used;

FIG. 3 is a diagram that shows fastening positions of a control board;

FIG. 4A is a diagram that describes a fastening structure of the present embodiment;

FIG. 4B is a diagram that describes rigid-fixing in the Related Art for describing a difference from the fastening structure of the present embodiment;

FIG. 5A is a diagram that shows another example of the fastening structure of the present embodiment in which a washer that is made of a viscoelastic material and has a protrusion section is used;

FIG. 5B is a diagram that shows another example of the fastening structure of the present embodiment in which a washer that is made of a viscoelastic material and does not have a protrusion section is used;

FIG. 6A is a diagram that shows still another example of the fastening structure of the present embodiment in which a washer that is made of a viscoelastic material and has a protrusion section is used; and

FIG. 6B is a diagram that shows still another example of the fastening structure of the present embodiment in which a washer that is made of a viscoelastic material and does not have a protrusion section is used.

### DETAILED DESCRIPTION OF EMBODIMENTS

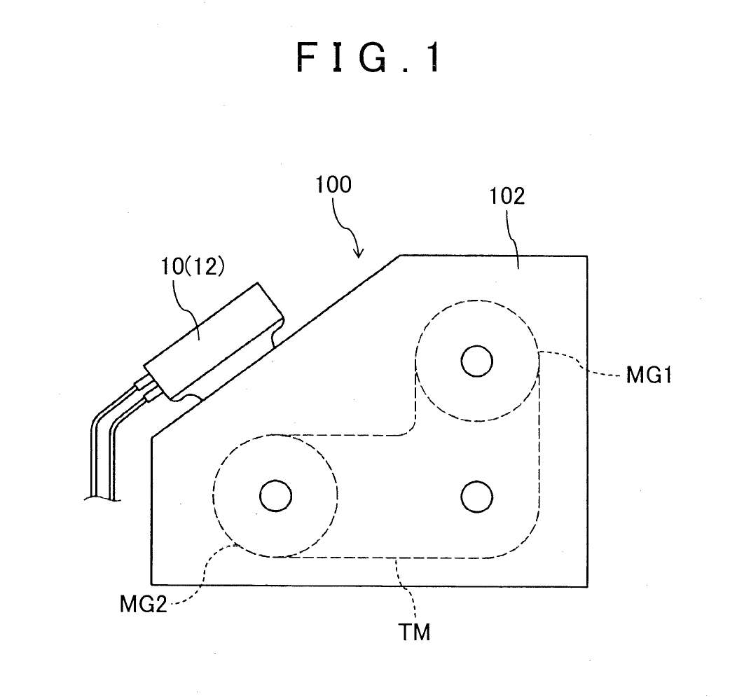

Hereinafter, a fastening structure of a control board 34 which is an embodiment of the present invention will be described with reference to FIGS. 1 to 6B. At first, a power control unit (PCU) 10 in which the control board 34 is disposed will be briefly described with reference to FIG. 1. FIG. 1 is a diagram that shows an installation state of the PCU 10 in an electric vehicle.

The PCU 10 is a unit that is mounted on an electric vehicle such as a hybrid automobile and an electric automobile and incorporates an inverter and a step up/down converter for controlling electric power supplied to an on-vehicle motor generator or electric power generated by the motor generator. In the present embodiment, the PCU 10 is placed directly on a case of a transaxle 100 (transaxle case 102).

The transaxle 100 includes two motor generators MG1 and MG2 and a transmission TM that transmits an output of a power source (motor and engine) to an axle. The motor generators MG and the transmission TM are housed in the transaxle case 102 and installed in an engine compartment. The PCU 10 is, as shown in FIG. 1, attached directly to a top surface of the transaxle case 102.

The PCU 10 has a PCU case 12 made of a metal such as aluminum, and inside thereof, electronic components that constitute an inverter and a step up/down converter, for example, a reactor, a capacitor, a switching element, and a control board 34 that controls the switching element are housed. Since installation techniques of the reactor, capacitor, and switching element among these are well known techniques, description thereof will be omitted. Hereinafter, an installation technique of the control board 34 will be described in detail.

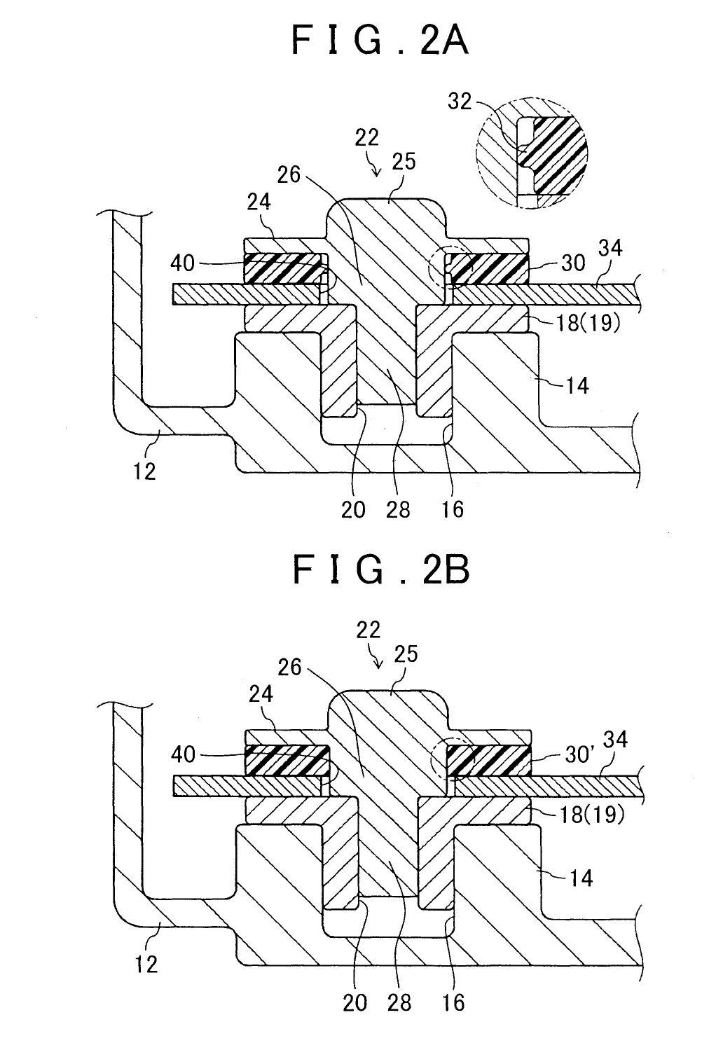

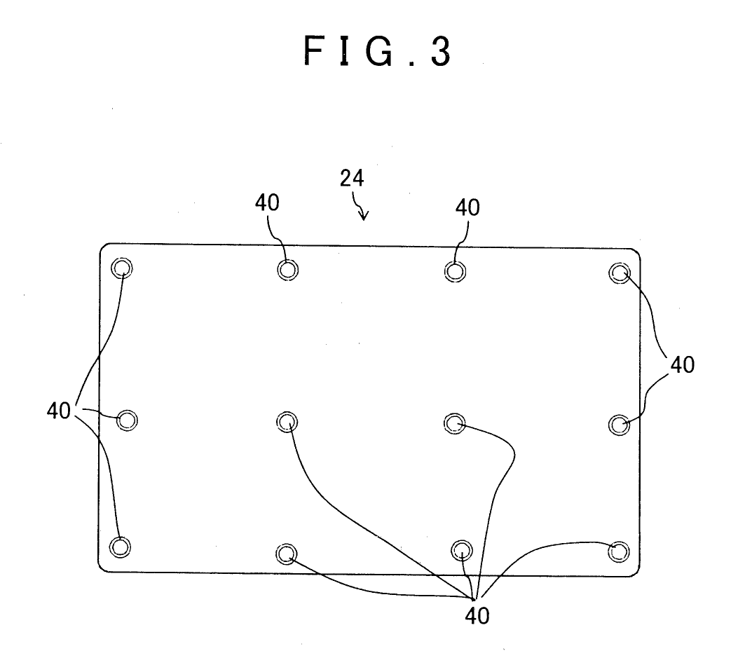

FIG. 2A and FIG. 2B are diagrams that show a fastening structure of the control board 34. FIG. 3 is a diagram that shows fastening positions (positions of the fitting holes 40) of the control board 34. In FIG. 3, various circuit elements that are mounted on the control board 34 are omitted from showing in the drawing.

The control board 34 is bolted and fastened to an inner surface of the PCU case 12 at multipoint. A structure in each of the fastening positions is as shown in FIG. 2A and FIG. 2B. That is, among the PCU case 12, at each of the positions corresponding to the fastening positions, a boss seat 14 that is a roughly cylindrical protrusion protruded to an inner surface side is provided. At a center of the boss seat 14, an insertion hole 16 that extends in an axial direction (a case thickness direction) is provided.

In the insertion hole 16, a nut 18 made of a metal such as iron is inserted and fixed and a nut section is provided. At a center of the nut 18, a female screw 20 that extends in an axial direction is provided. Further, at an upper end of the nut 18, a guard section 19 having a diameter larger than that of the insertion hole 16 is disposed, and a top surface of the guard section 19 is a seat face that contacts with a step surface of the bolt 22. In the present embodiment, although the nut 18 and the PCU case 12 are shown as separate bodies, these may be integrated, for example, the female screw 20 may be provide directly on the boss seat 14 of the PCU case 12. When the female screw 20 is provided directly to the PCU case 12, such that an abutting surface with the control board 34 may not be worn by scrubbing, the PCU case 12 is desirable to be formed from a high-hard material or the abutting surface is coated with a wear-protecting coating.

Among the control board 34 that is a target to be fastened, the fixing hole 40 is provided at a position corresponding to a position to be fastened. As shown in FIG. 3, a plurality of the fixing holes 40 is dispersed and provided over an entire board. An inner diameter of each of the fixing holes 40 is sufficiently larger than that of the intermediate section 26 of the bolt 22 described below and smaller than an outer diameter of a flange 24 of the bolt 22. On a back surface of the control board 34, a ground line is provided and can contact with the nut 18 described below.

The bolt 22 for screwing and fastening the control board 34 to the nut 18 is provided into a stepped structure that has the intermediate section 26 in which the female screw 20 is not provided between the head 25 having the flange 24 and a male screw section 28 that is screwed to the female screw 20 of the nut 18. The intermediate section 26 has a diameter larger than that the male screw section 28 and smaller than those of the flange 24 and the fixing hole 40. Further, a length of the intermediate section 26 is slightly smaller than a total value of a thickness of the control board 34 and a thickness of washer 30. Therefore, when the bolt 22 is screwed to the nut 18 until a stepped surface of the intermediate section 26 and the male screw section 28 comes into contact with a seat face of the nut 18, due to the flange 24 of the bolt 22, the washer 30 is slightly pressed and compressed.

The washer 30 is disposed between the control board 34 and the flange 24. The washer 30 is a circular member made of a viscoelastic material and an inner diameter thereof is larger than an outer diameter of the intermediate section 26 and smaller than an outer diameter of the flange 24. Herein, the viscoelasticity is a property in which when an external force is applied, a material deforms as a time goes, and when the external force is removed, the material recovers near to an original shape. The washer 30 made of the viscoelastic material generates strain at the same time when the external force is applied. When the external force is constant, the stress becomes constant while gradually decelerating as the time goes. Then, at the same time as the external force is removed, the strain decreases, and, although a decreasing amount thereof becomes constant while decelerating, finally the strain does not disappear and remains slightly. As materials having the viscoelasticity like this, a rubber, in particular, an ethylene propylene diene rubber (EPDM) can be used. The washer 30 has a flat annular shape, in other words, a shape having flat top and bottom surfaces, and comes into surface contact with a bottom surface of the flange 24 and a top surface of the control board 34. In an inner peripheral surface of the washer 30 shown in FIG. 2A, a protrusion section 32 that protrudes inwardly is provided on an inner peripheral surface of the washer 30 shown in FIG. 2A. Herein as shown in FIG. 2B, a washer 30′ in which on an inner peripheral surface a protrusion section is not provided may be adopted.

Next, a reason why a fastening structure such as described above is adopted will be described. As described above, in the present embodiment, the PCU 10 is placed directly on the transaxle case 102. In this case, since the PCU 10 that controls electric power of the motor generators MG1 and MG2 can be disposed in the vicinity of the motor generators MG1 and MG2, a wiring can be shortened and a space can be effectively used. However, on the other hand, the transaxle 100 tends to generate a vibration including high frequency vibrations accompanying a drive of the motor generators MG1 and MG2 and the transmission TM. When the PCU 10 is placed directly on the transaxle 100 like this, both of a level and a frequency of the vibration that is input in the PCU 10 become larger. Herein, in order to reduce an influence inflicted by such a vibration on the control board 34, it is considered to adopt the PCU case 12 having high stiffness and to fasten the control board 34 to the PCU case 12 at multipoint.

Herein, the conventional bracket that fastens the board is provided of a resin in many cases, and, in order to improve the stiffness of the bracket, it is necessary in many cases to increase a thickness or to add a rib. Further, since also a space for fastening the bracket to the PCU case 12 is necessary, a size of an entire case becomes larger in many cases. Still further, in recent years, since a heat generation density tends to increase due to an increase in packaging density of the board, an efficient heat dissipation mechanism is indispensable, and, in order to externally release heat from the control board 34, a separate component made of a material having high thermal conductivity such as a Sarcon sheet or a bus bar was necessary. Further, since the resin case is nonconductive, in order to ground the control board 34, a separate component made of a conductive material such as the bus bar was necessary to be disposed. That is, in the case where the resin case was used, a separate component is necessary for heat release and grounding, there was a fear of causing a cost increase and a further size increase.

In the present embodiment, as the PCU case 12, a metallic case made of a metal such as aluminum is adopted. When the metal is adopted as a material of the PCU case 12, without increasing an entire size of the case, high stiffness can be secured. Further, the metal has excellent electric conductivity and thermal conductivity compared with the resin. Therefore, the metallic case itself can be utilized in grounding and heat release of the control board 34. In other words, when the board is fastened directly to the metallic case, miniaturization due to omission of the bracket can be realized, and, grounding and heat release can be realized without adding other component. Therefore, the cost increase and further size increase can be prevented.

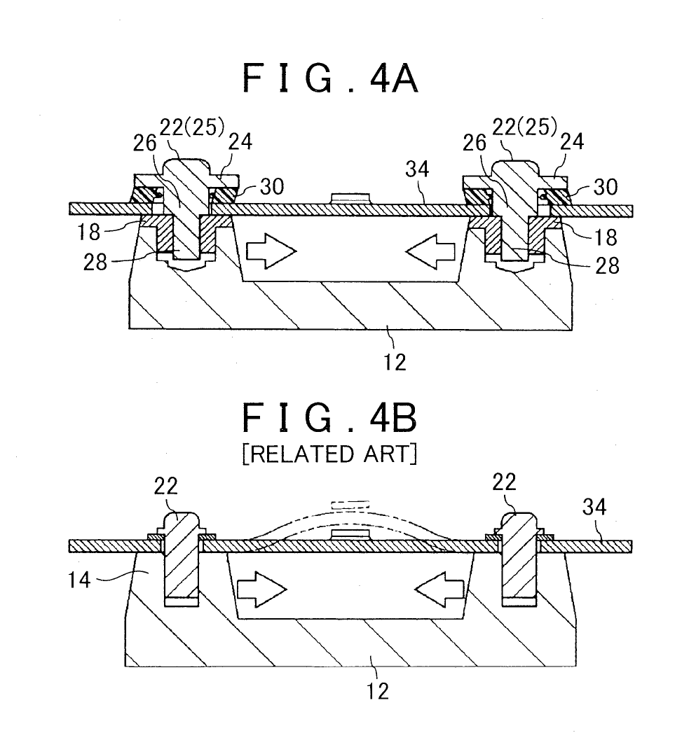

However, when the control board 34 is fastened at multipoint to an inner surface of the metallic PCU case 12, due to a difference of thermal expansion coefficients of the PCU case 12 and the control board 34, stress works in a surface direction of the control board 34 in some cases. Regarding this, a description will be given with reference to FIG. 4B. FIG. 4B is an image diagram that shows a case when the control board 34 is rigid-fixed, that is, fixed and fastened to an inner surface of the metallic PCU case 12 such that the control board 34 may not move with respect to the PCU case 12.

According to an example of the related art shown in FIG. 4B, the boss seat 14 on which a female screw is provided is disposed on an inner surface of the PCU case 12, the head of the bolt 22 screwed together with the female screw and the boss seat sandwiches the control board 34. In the case of the fastening structure like this, the control board 34 is positionally fixed with respect to the PCU case 12.

Herein, the control board 34 is usually provided by mounting various circuit elements by soldering on a printed wiring board on which a circuit pattern is provided with a copper foil. The printed wiring board is formed of a resin such as a glass fiber reinforced epoxy resin that is an insulator and has a linear expansion coefficient smaller than that of a metal that provides the PCU case 12. Therefore, when the control board 34 is rigid-fixed to the PCU case 12, there occurs a problem that the control board 34 cannot follow expansion and contraction of the PCU case 12 that has a large linear expansion coefficient.

That is, in the inside of a vehicle, a temperature differs largely between day and night, summer and winter, and running time and standing time. Accompanying this temperature change, the metallic PCU case 12 having a larger linear expansion coefficient expands and contracts and also a distance between boss seats expands and contracts. On the other hand, since the printed wiring board that provides the control board 34 is made of a resin having a linear expansion coefficient smaller than that of the metal, an expansion and contraction amount of a distance between fixing holes accompanying the temperature change is smaller than the expansion and, contraction amount of the distance between the boss seats.

For example, in winters, when the inside of a vehicle becomes a low temperature, the control board 34 contracts. However, more than a contraction amount of the control board 34, the PCU case 12 contracts. Accompanying the contraction of the PCU case 12, a distance between the bolts screwed to the PCU case 12 becomes smaller than a distance between the fixing holes provided on the control board 34, and the bolt 22 presses the control board 34 in a surface direction. Due to the pressing, a compression stress works on the control board 34, and, in FIG. 4B, a bend is generated in the control board 34 as shown with a two-dot chain line.

On the contrary, in summers, when a temperature inside of the vehicle becomes higher, the control board 34 expands. However, more than the expansion amount of the control board 34, the PCU case 12 expands. Accompanying the expansion of the PCU case 12, since the bolts 22 of which inter-bolt distance is expanded press the control board 34 in a surface direction, tensile stress works to the control board 34.

That is, since, due to repetition of the temperature change, compression stress and tensile stress are repeatedly applied to the control board 34, the control board 34 and the circuit pattern are fatigue fractured and the solder that fixes the circuit element is cracked.

The reason why the fastening structure that uses the stepped bolt 22 and the washer 30 made of the viscoelastic material is adopted in the present embodiment is to avoid such problems. Regarding this, a description is given with reference to FIG. 4A. FIG. 4A is a schematic view of the fastening structure of the present embodiment.

As described above, in the present embodiment, the intermediate section 26 in which the female screw 20 is not provided is disposed between the head 25 of the bolt 22 and the male screw section 28. Therefore, when the bolt 22 is screwed into the female screw 20 of the nut 18, a stepped surface between the intermediate section 26 and the male screw section 28 abuts on a seat face (top surface) of the nut 18. Thus, when the screw is fastened under a constant torque, an axial force of the screw is generated in the abutting section. As a result, a backlash of the bolt 22 due to settling of the washer 30 or the control board 34 can be effectively prevented and the pressing load of the control board 34 can be maintained constant.

Between the bolt head 25 and the control board 34, the washer 30 made of a viscoelastic material is disposed. The washer 30 is compressed by a constant amount by the bolt head 25, and due to a viscoelastic repulsion force, the control board 34 is pressed against the seat face of the nut 18. Thus, when the control board 34 is pressed by the viscoelastic repulsion force of the viscoelastic material, an excessive force can be prevented from being applied on the fastening positions of the control board 34. Further, due to the viscoelastic characteristics of the washer 30, the control board 34 can be fastened without co-oscillating with an up and down vibration of high frequencies. In particular, when the PCU 10 is placed directly on the transaxle case 102, a vibration of high frequencies is generated accompanying the drive of the motor generators. However, in the present embodiment, since the washer 30 made of a viscoelastic material is brought into surface contact with the control board 34, the spring constant of the fastening position becomes larger as the frequency becomes larger, thus, the control board 34 can be fastened without co-oscillating even in a high frequency.

Further, the washer 30 made of the viscoelastic material can absorb a shift generated by a difference of the linear expansion coefficients of the PCU case 12 and the control board 34. For example, a case where the inside of the vehicle becomes a low temperature and the PCU case 12 contracts will be considered. In this case, the nuts 18 and the bolts 22 that are fastened to the PCU case 12 slide and move, as shown in FIG. 4A, in a direction where distances between nuts and between bolts become smaller. Here, since the fixing hole 40 of the control board 34 has a diameter larger than that of the intermediate section 26 of the bolt 22, even when the bolt 22 slides and moves, the bolt 22 does not touch with the control board 34, therefore, the control board 34 does not receive a force in a surface direction from the bolt 22. Further, since the washer 30 that is made of a viscoelastic material and is interposed between the bolt 22 and the control board 34 has a high friction coefficient, without slipping with respect to the bolt 22 and the control board 34, a state in contact with both is maintained. Further, since the washer 30 made of the viscoelastic material has the viscoelasticity and, by shear-deforming, a positional displacement of the bolt 22 and the control board 34 accompanying a slide movement of the bolt 22 can be absorbed.

Further, in the present embodiment, the protrusion section 32 that protrudes inwardly and comes into contact with the bolt 22 is disposed on an inner peripheral surface of the washer 30. When the bolt 22 slides and moves, also the protrusion section 32 deforms and absorbs a force pressing in a surface direction of the bolt 22. As a result, a force in a surface direction acting on the control board 34 can be more reduced.

As described above, by interposing the washer 30 made of the viscoelastic material, a difference of the linear expansion coefficients between the PCU case 12 and the control board 34 can be absorbed, and stress in a surface direction can be prevented from acting on the control board 34. As a result, the fatigue fracture of the circuit pattern provided on the control board 34 and solder crack can be effectively prevented and the reliability of the control board 34 can be improved. Further, since, due to the viscoelasticity characteristics of the washer 30, the spring constant of the washer 30 becomes larger accompanying the frequency, also in a high frequency, the control board 34 can be fastened without co-oscillating with an up-and-down vibration.

Further, in the present embodiment, the control board 34 is placed directly on the seat face on an iron nut 18. Therefore, heat generated in the control board 34 is efficiently transmitted via the iron nut 18 having high thermal conductivity to the PCU case 12. As a result, without using a separate component such as a Sarcon sheet, the heat generated in the control board 34 can be efficiently released, resultantly, miniaturization and cost reduction of the PCU 10 can be realized. Further, since the heat can be efficiently released, further higher densification of the control board 34 becomes possible and further miniaturization can be realized.

Still further, when the ground line disposed on a back surface of the control board 34 is brought into contact with the seat face of the iron nut 18, without using a separate component such as the bus bar, the ground line and the PCU case 12 can be electrically connected. As a result, while the size and cost of the PCU 10 are reduced, the noise also can be reduced.

As described in the above, according to the present embodiment, while reducing an influence of the vibration, the reliability of the PCU 10 can be improved, and miniaturization and cost reduction of the PCU 10 can be made possible.

In the present embodiment, the control board 34 is fastened to the PCU case 12 at multipoint. However, only one of the plurality of fastening positions is desirably rigid-fixed by pressing the control board 34 with the head of the bolt or the metallic washer without intervening the washer 30 made of the viscoelastic material. When only one position is rigid-fixed and a relative positional relationship of the PCU case 12 and the control board 34 is fixed, the control board 34 can vibrate in a surface direction. The fastening position that is rigid-fixed is not particularly limited. However, for example, the vicinity of a connector to which a wiring that supplies communication or a power source is connected or the vicinity of the ground line may be rigid-fixed. When the vicinity of the ground line is rigid-fixed, the ground line is desirably provided in a position that can contact with the head of the bolt or the metallic washer among a top surface of the control board 34. When such a structure is used, since the ground line does not grind with the bolt 22 and the nut 18, communication reliability of the ground line can be improved.

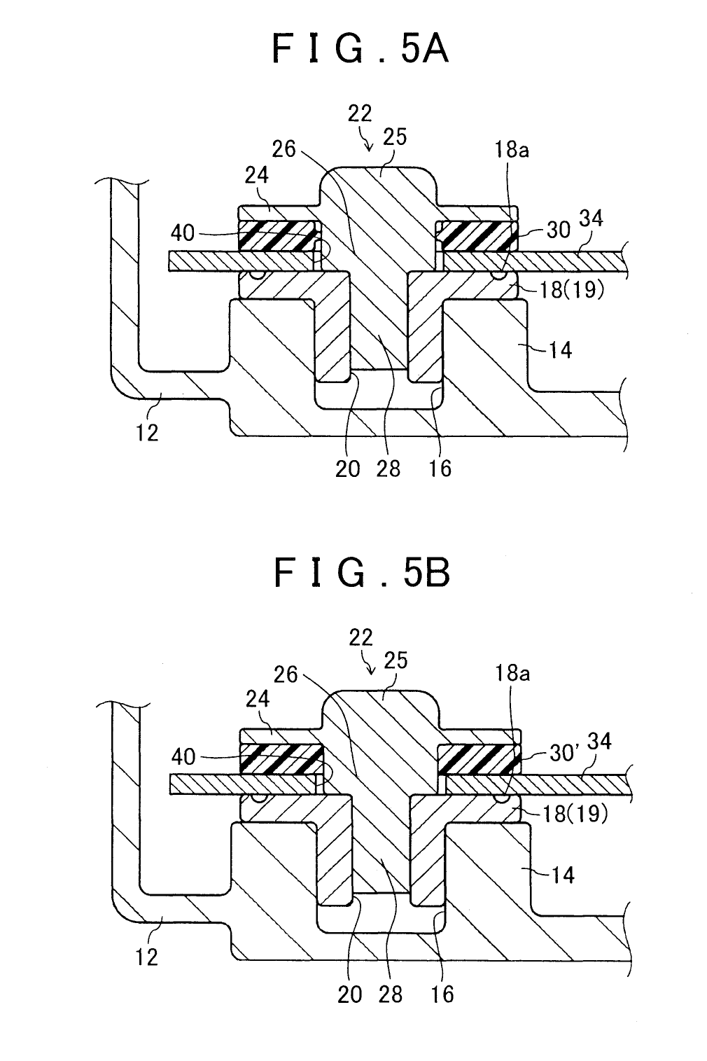

Further, as shown in FIG. 5A and FIG. 5B, a recess section 18a provided by a groove or a processed pattern may be provided on a top surface of the nut 18. When such a recess section 18a is provided, even when an extraneous material is generated by grinding of the nut 18 and the control board 34, the extraneous material stays in the recess section 18a and can be prevented from falling thereby. A shape of the recess section 18a is not particularly limited. However, a shape that does not reach an outer periphery of the seat face in a top view, for example, a circle is desirable. Further, in order to suppress the extraneous material from being generated accompanying grinding of the nut 18 and the control board 34, a lubricant such as grease may be coated between the nut 18 and the control board 34 or a coating (fluorine coating, for example) that improves the slidability may be applied on the seat face of the nut 18.

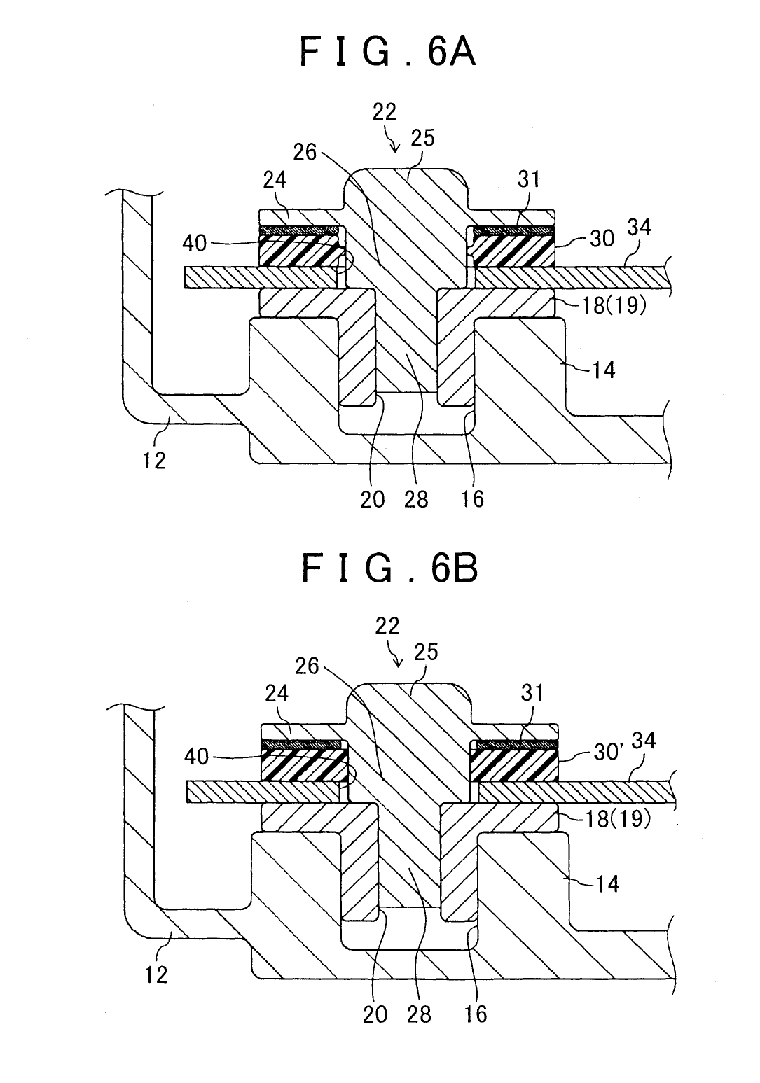

Still further, as shown in FIG. 6A and FIG. 6B, a washer 31 made of a metal may be disposed between the washer 30 or 30′ made of the viscoelastic material and the head 25 (flange 24) of the bolt 22. When such a metallic washer 31 is disposed, the friction coefficient between the bolt 22 and the washer 30 or 30′ made of the viscoelastic material can be made smaller, and the washer 30 or 30′ made of the viscoelastic material can be prevented from being twisted due to a torque during fastening the bolt. Further, without disposing the metallic washer 31, a coating that can reduce the friction may be applied on at least one of a top surface of the washer 30 or 30′ made of, the viscoelastic material and a bottom surface of the bolt head 25.

1. A fastening structure for fastening a control board to a metallic case of a power control unit, the power control unit being placed directly on an on-vehicle transaxle, the fastening structure comprising:
a nut section disposed on an inner surface of the metallic case, the nut section having a female screw;
a bolt disposed in a fixing hole provided in the control board, the bolt being screwed with the nut section; and
a washer made of a viscoelastic material, the washer being provided between a head of the bolt and the control board, and the washer configured to come into surface contact with a bottom surface of the head of the bolt and a top surface of the control board,
wherein the bolt includes a male screw section, an intermediate section and the head, the male screw section being screwed with the female screw, the intermediate section having a diameter larger than a diameter of the male screw section and smaller than a diameter of the fixing hole,
in the intermediate section a stepped surface with respect to the male screw section is in contact with a seat face that is an end surface of the nut section, and
the head has a diameter larger than the diameter of the intermediate section and the bottom surface of the head configured to come into contact with a top surface of the washer made of the viscoelastic material.

2. The fastening structure according to claim 1, wherein a protrusion section is provided on an inner peripheral surface of the washer made of the viscoelastic material, the protrusion section protrudes inwardly and contacts with an outer peripheral surface of the intermediate section of the bolt.

3. The fastening structure according to claim 1, wherein a metallic washer is provided between the washer made of the viscoelastic material and the head of the bolt.

4. The fastening structure according to claim 1, wherein a friction-reducing coating is applied on at least one of the top surface of the washer made of the viscoelastic material and the bottom surface of the head of the bolt.

5. The fastening structure according to claim 1, wherein a recess section is provided on a part of a surface of the nut section, where the nut section comes into surface contact with the control board.

6. The fastening structure according to claim 1, wherein the control board is fastened to the metallic case at a plurality of positions, only one of the plurality of positions being rigid-fixed with a washer not made of the viscoelastic material, and remaining positions of the plurality of positions being fastened with the washers made of the viscoelastic material.
